(19) United States
(12) Patent Application Publication
(10) Pub. No.: US 2024/0228363 A1
(43) Pub. Date: Jul. 11, 2024

(54) GLASS COMPOSITION, GLASS ARTICLE PREPARED THEREFROM, AND DISPLAY DEVICE

(71) Applicants: Samsung Display Co., LTD., Yongin-si (KR); Kongju National University Industry-University Cooperation Foundation, Gongju-si (KR)

(72) Inventors: Gyu In SHIM, Yongin-si (KR); Woon Jin CHUNG, Seongnam-si (KR); Min Gyeong KANG, Jinju-si (KR); Seung KIM, Yongin-si (KR); Seung Ho KIM, Yongin-si (KR); Kyeong Dae PARK, Cheonan-si (KR); Seong Young PARK, Cheonan-si (KR); Cheol Min PARK, Yongin-si (KR); Hui Yeon SHON, Yongin-si (KR); Jae Gil LEE, Yongin-si (KR); Jin Won JANG, Yongin-si (KR); So Mi JUNG, Yongin-si (KR)

(73) Assignees: Samsung Display Co., LTD., Yongin-si (KR); Kongju National University Industry-University Cooperation Foundation, Gongju-si (KR)

(21) Appl. No.: 18/456,911

(22) Filed: Aug. 28, 2023

(30) Foreign Application Priority Data
Jan. 10, 2023 (KR) 10-2023-0003465

(51) Int. Cl. C03C 3/091; H05K 5/03

(52) U.S. Cl. CPC C03C 3/091; H05K 5/03

(57) ABSTRACT

A glass article prepared from a glass composition includes SiO₂ in a range of about 48 mol % to about 57 mol %, Al₂O₃ in a range of about 10 mol % to about 20 mol %, Na₂O in a range of about 8 mol % to about 18 mol %, K₂O greater than 0 mol % and equal to or less than about 10 mol %, B₂O₃ in a range of about 10 mol % to about 17 mol %, and CaO or MgO greater than 0 mol % and equal to or less than about 7 mol % based on a total weight. A ration of Al₂O₃ and Na₂O+K₂O is in a range of about 0.7 to about 1.3, and a thickness of the glass article is equal to or less than about 100 μm.

### CROSS REFERENCE TO RELATED APPLICATION(S)

This application claims priority to and benefits of Korean Patent Application No. 10-2023-0003465 under 35 U.S.C. § 119, filed on Jan. 10, 2023, in the Korean Intellectual Property Office (KIPO), the entire contents of which are incorporated herein by reference.

### BACKGROUND

### 1. Technical Field

The disclosure relates to a glass composition, a glass article prepared therefrom, and a display device.

### 2. Description of the Related Art

Glass articles are widely used in electronic devices including display devices, construction materials, or the like. For example, glass articles are employed as a substrate for a flat-panel display device such as a liquid-crystal display (LCD) device, an organic light-emitting display (OLED) device, an electrophoretic display (EPD) device, and the like, or a window for protecting the flat panel display devices.

As portable electronic devices such as smart phones, tablet PCs, and the like prevail, a glass article employed thereby is frequently exposed to external impact. There is a demand for the development of glass articles that are thin that are readily carriable and can withstand external shocks.

Recently, a foldable display device has been studied for user convenience. A glass article applied to a foldable display device is required to have a thin thickness in order to relieve bending stress when it is folded and to have strength to withstand external shock. Accordingly, there have been attempts to improve the strength of a thin glass article by changing the composition ratio of the glass article and the production process conditions.

### SUMMARY

The disclosure provides a glass composition having a novel composition ratio, a glass article prepared therefrom, and a display device including the glass article.

It should be noted that objects of the disclosure are not limited to the above-mentioned object; and other objects of the disclosure will be apparent to those skilled in the art from the following descriptions.

According to an embodiment of the disclosure, a glass article prepared from a glass composition may include SiO₂ in a range of about 48 mol % to about 57 mol %, Al₂O₃ in a range of about 10 mol % to about 20 mol %, Na₂O in a range of about 8 mol % to about 18 mol %, K₂O greater than 0 mol % and equal to or less than about 10 mol %, B₂O₃ in a range of about 10 mol % to about 17 mol %, and CaO or MgO greater than 0 mol % and equal to or less than about 7 mol % based on a total weight. The glass composition may satisfy Condition 1 below:

$$about 0.7 \leq {Al}_{2} {O}_{3} / ( {Na}_{2} O + {K}_{2} O ) \leq about 1.3 , \qquad [ Condition 1 ]$$

and

Al₂O₃, Na₂O, and K₂O may be contents in mol % in the glass composition, and a thickness of the glass article may be equal to or less than about 100 μm.

In an embodiment, the thickness of the glass article may be in a range of about 20 μm to about 100 μm.

In an embodiment, a glass transition temperature of the glass article may be in a range of about 510° C. to about 610° C.

In an embodiment, a density of the glass article may be in a range of about 2.45 g/cm³ to about 2.60 g/cm³.

In an embodiment, a modulus of elasticity of the glass article may be in a range of about 60 GPa to about 70 GPa.

In an embodiment, a hardness of the glass article may be in a range of about 4.8 GPa to about 5.5 GPa.

In an embodiment, a fracture toughness of the glass article may be in a range of about 0.75 MPa*m^{0.5} to about 0.83 MPa*m^{0.5}.

In an embodiment, a brittleness of the galls article may be in a range of about 6.0 μm^{-0.5} to about 7.0 μm^{-0.5}.

In an embodiment, a coefficient of thermal expansion of the glass article may be in a range of about 80*10⁻⁷ K⁻¹ to about 90*10⁻⁷ K⁻¹.

In an embodiment, a Poisson ratio of the glass article may be in a range of about 0.23 to about 0.25.

In an embodiment, a crack initiation load of the glass article may be in a range of about 1,500 gf to about 2,500 gf.

In an embodiment, a fractional free volume of the glass article may be in a range of about 15,000 to about 20,000.

In an embodiment, an average of a pen drop breakage height of the glass article may be greater than or equal to about 2.5 cm.

According to an embodiment of the disclosure, a glass composition may include SiO₂ in a range of about 48 mol % to about 57 mol %, Al₂O₃ in a range of about 10 mol % to about 20 mol %, Na₂O in a range of about 8 mol % to about 18 mol %, K₂O greater than 0 mol % and equal to or less than about 10 mol %, B₂O₃ in a range of about 10 mol % to about 17 mol %, and CaO or MgO greater than 0 mol % and equal to or less than about 7 mol % based on a total weight. The glass composition may satisfy Condition 1 below:

$$about 0.7 \leq {Al}_{2} {O}_{3} / ( {Na}_{2} O + {K}_{2} O ) \leq about 1.3 , \qquad [ Condition 1 ]$$

and

Al₂O₃, Na₂O, and K₂O may be contents in mol % in the glass composition.

According to an embodiment of the disclosure, a display device may include a display panel including a plurality of pixels, a cover window disposed above the display panel, and an optically transparent coupling layer disposed between the display panel and the cover window. The cover window may be prepared from a glass composition including SiO₂ in a range of about 48 mol % to about 57 mol %, Al₂O₃ in a range of about 10 mol % to about 20 mol %, Na₂O in a range of about 8 mol % to about 18 mol %, K₂O greater than 0 mol % and equal to or less than about 10 mol %, B₂O₃ in a range of about 10 mol % to about 17 mol %, and CaO or MgO greater than 0 mol % and equal to or less than about 7 mol % based on a total weight. The glass composition may satisfy Condition 1 below:

$$about 0.7 \leq {Al}_{2} {O}_{3} / ( {Na}_{2} O + {K}_{2} O ) \leq about 1.3 , \qquad [ Condition 1 ]$$

and

Al₂O₃, Na₂O, and K₂O may be contents in mol % in the glass composition, and a thickness of the cover window may be equal to or less than about 100 μm.

In an embodiment, the thickness of the cover window may be in a range of about 20 μm to about 100 μm.

In an embodiment, a glass transition temperature of the cover window may be in a range of about 510° C. to about 610° C.

In an embodiment, a density of the cover window may be in a range of about 2.45 g/cm³ to about 2.60 g/cm³.

In an embodiment, a modulus of elasticity the cover window may be a modulus of elasticity in a range of about 60 GPa to about 70 GPa.

In an embodiment, a hardness of the cover window may be in a range of about 4.8 GPa to about 5.5 GPa.

In an embodiment, a fracture toughness of the cover window may be a fracture toughness in a range of about 0.75 MPa*m^{0.5} to about 0.83 MPa*m^{0.5}

In an embodiment, a brittleness of the cover window may be in a range of about 6.0 μm^{-0.5} to about 7.0 μm^{-0.5}.

In an embodiment, a coefficient of thermal expansion of the cover window may be in a range of about 80*10⁻⁷ K⁻¹ to about 90*10⁻⁷ K⁻¹.

In an embodiment, a Poisson ratio of the cover window may be in a range of about 0.23 to about 0.25.

In an embodiment, a crack initiation load of the cover window may be in a range of about 1,500 gf to about 2,500 gf.

In an embodiment, a fractional free volume of the cover window may be in a range of about 15,000 to about 20,000.

According to an embodiment of the disclosure, a glass composition may have a novel composition ratio, and a glass article prepared therefrom may have excellent mechanical strength, surface strength, and impact resistance while having flexibility. In particular, the glass article may have excellent processability and sufficient flexibility and strength for a foldable display device.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of glass articles according to embodiments of the disclosure.

FIG. 2 is a schematic perspective view of a display device employing a glass article according to an embodiment of the disclosure in case that the display device is unfolded.

FIG. 3 is a schematic perspective view of the display device of FIG. 2 in case that the display device is folded.

FIG. 4 is a schematic cross-sectional view of a glass article being employed as a cover window of a display device according to an embodiment of the disclosure.

FIG. 5 is a schematic cross-sectional view of a glass article having a shape of a flat plate according to an embodiment of the disclosure.

FIG. 6 is a schematic graph showing a stress profile of a glass article according to an embodiment of the disclosure.

FIG. 7 is a schematic flowchart for illustrating processing steps for producing a glass article according to an embodiment of the disclosure.

FIG. 8 is a schematic flowchart illustrating processing steps from a cutting to a post-strengthening surface polishing of FIG. 7.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising.” “includes,” and/or “including.” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially.” “about,” and other similar terms, are used as terms of approximation and not as terms of degree, and, as such, are utilized to account for inherent deviations in measured, calculated, and/or provided values that would be recognized by one of ordinary skill in the art.

It will also be understood that when a layer is referred to as being “on” another layer or substrate, it can be directly on the other layer or substrate, or intervening layers may also be present. The same reference numbers indicate the same components throughout the specification. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ.

It will be understood that when an element such as a layer, film, region, or substrate is referred to as being “on” or “over” another element, it can be directly on the other element or intervening element(s) may also be present. In contrast, when an element is referred to as being “directly on” another element, no intervening elements are present.

When a component is described herein to “connect” another component to the other component or to be “connected to” other components, the components may be connected to each other as separate elements, or the components may be integral with each other.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Spatially relative terms, such as “below,” “lower,” “above.” “upper,” “over.” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The display surface may be parallel to a surface defined by a first direction DR1 and a second direction DR2. A normal direction of the display surface, i.e., a thickness direction of the display device DD, may indicate a third direction DR3. In this specification, an expression of “when viewed from a top or in a plan view” may represent a case when viewed in the third direction DR3. Hereinafter, a front surface (or a top surface) and a rear surface (or a bottom surface) of each of layers or units may be distinguished by the third direction DR3. However, directions indicated by the first to third directions DR1, DR2, and DR3 may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Each of the features of the embodiments of the disclosure may be combined or combined with each other, in part or in whole, and technically various interlocking and driving are possible. Each embodiment may be implemented independently of each other or may be implemented together in an association.

Hereinafter, embodiments of the disclosure will be described with reference to the accompanying drawings.

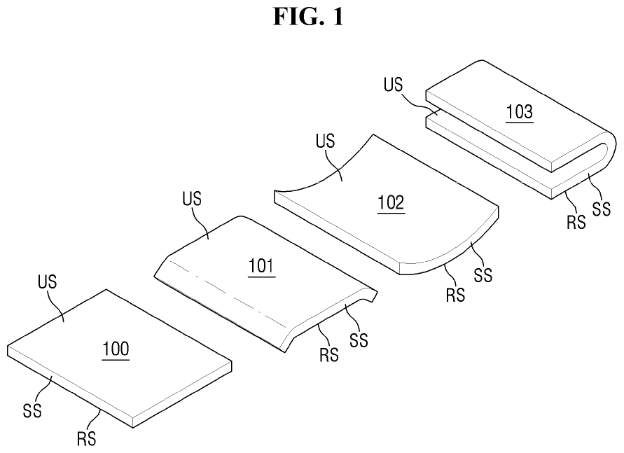

FIG. 1 is a schematic perspective view of glass articles according to embodiments of the disclosure.

Glass may be used as a cover window for protecting a display device, a substrate for a display panel, a substrate for a touch panel, an optical member such as a light guide plate and the like in electronic devices including a display device, such as a tablet PC, a notebook PC, a smart phone, an electronic book, a television and a PC monitor as well as a refrigerator, a washing machine including a display screen, and the like. Glass may also be employed as a cover glass for an instrument panel in a vehicle, a cover glass for solar cells, interior materials for construction materials, windows for buildings and houses, and the like.

Glass may be required to have high strength. For example, in case that glass is employed as a cover window, it may be desirable to have a thin thickness and a high strength such that the cover window is not readily broken by an external impact, since the cover window is required to have a high transmittance and a low weight. Glass having a high strength may be produced by, for example, chemical strengthening, thermal tempering, or the like. A variety of shapes of strengthened glasses are shown in FIG. 1.

Referring to FIG. 1, in an embodiment, a glass article 100 may have a shape of a flat sheet or a flat plate. In another embodiment, glass articles 101, 102, and 103 may have a three-dimensional shape including bent portions. For example, an edge of a flat portion may be curved (e.g., the glass article 101), an entire surface may be curved (e.g., the glass article 102) or folded (the glass article 103). In another embodiment, the glass article 100 may have a flat sheet or flat plate shape, may be flexible, and may be folded, stretched, or rolled.

The shape of the glass articles 100 to 103 may be, but is not limited to, a rectangle in a plan view. For example, the glass articles 100 to 103 may have various shapes such as a rounded rectangle, a square, a circle, an ellipse, and the like in a plan view. In the following description, a glass article having a shape of a rectangular flat plate will be described as an embodiment of the glass articles 100 to 103. However, the disclosure is not limited thereto.

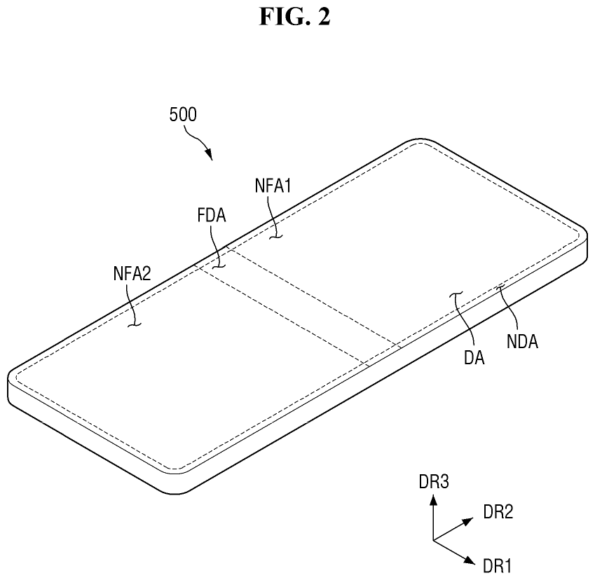

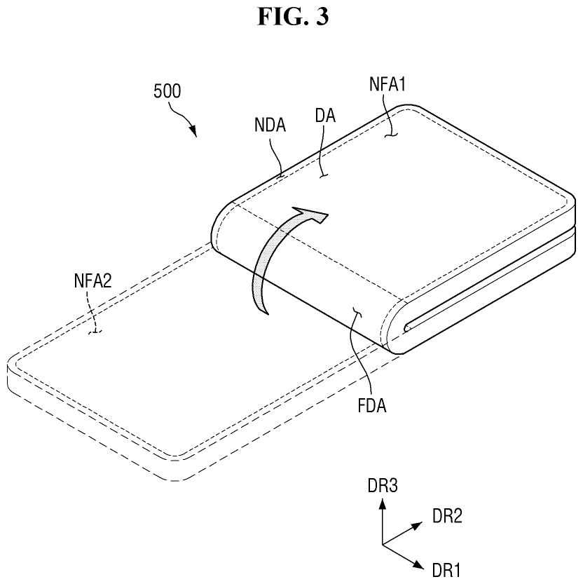

FIG. 2 is a schematic perspective view of a display device employing a glass article according to an embodiment of the disclosure in case that the display device is unfolded. FIG. 3 is a schematic perspective view of the display device of FIG. 2 in case that the display device is folded.

Referring to FIGS. 2 and 3, a display device 500 according to an embodiment may be a foldable display device. As will be described below, the display device 500 may employ the glass articles 100 to 103 of FIG. 1 as a cover window, and the glass articles 100 to 103 may be flexible and foldable.

As shown in FIGS. 2 and 3, a first direction DR1 may be a direction parallel to a side of the display device 500, for example, a horizontal direction of the display device 500 in a plan view. A second direction DR2 may be a direction parallel to another side of the display device 500 that meets the side of the display device 500, for example, a vertical direction of the display device 10 in a plan view. A third direction DR3 may be a thickness direction of the display device 500. The first direction DR1 may intersect the second direction DR2, and the second direction DR2 may intersect the third direction DR3.

According to an embodiment of the disclosure, the display device 500 may have a rectangular shape in a plan view. The display device 500 may have a rectangular shape with sharp corners or a rectangular shape with rounded corners in a plan view. The display device 500 may include two shorter sides extended in the first direction DR1 and two longer sides extended in the second direction DR2 in a plan view.

The display device 500 may include a display area DA and a non-display area NDA. A shape of the display area DA may correspond to the shape of the display device 500 in a plan view. For example, in case that the display device 500 is rectangular in a plan view, the display area DA may also be rectangular.

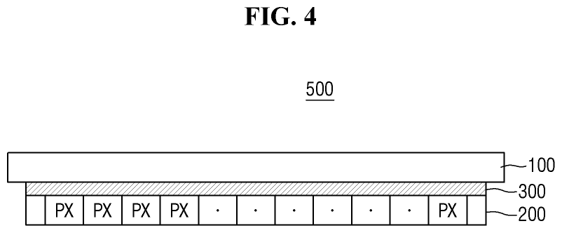

The display area DA may include multiple pixels (see, e.g., PX of FIG. 4) to display images. The pixels may be arranged in a matrix pattern. The shape of the pixels may be a rectangle, a diamond, a square, or the like in a plan view, but the disclosure is not limited thereto. For example, the shape of the pixels may be a quadrangle other than a rectangle, a diamond (or a rhombus), a square, a polygon other than a quadrangle, a circle, an ellipse, or the like in a plan view.

The non-display area NDA may not include pixels and may not display images. The non-display area NDA may be disposed adjacent to the display area DA. For example, the non-display area NDA may surround the display area DA, but the disclosure is not limited thereto. For example, the display area DA may be partially surrounded by the non-display area NDA.

According to an embodiment, the display device 500 may remain folded as well as unfolded. The display device 500 may be folded inward (in-folding manner) so that the display area DA is located inside, as shown in FIG. 3. In case that the display device 500 is folded inward (in-folding), a portion of an upper surface of the display device 500 may face another portion of the upper surface of the display device 500. In another embodiment, the display device 500 may be folded outward (out-folding) so that the display area DA is located outside. In case that the display device 500 is folded outward (out-folding), a portion of a lower surface of the display device 500 may face another portion of the lower surface of the display device 500.

According to an embodiment of the disclosure, the display device 500 may be a foldable display device. As used herein, a foldable display device may be a display device that can be folded and can be switched between a folded state and an unfolded state. In case that the display device 500 is folded, the display device 500 may be folded at an angle of about 180°. However, the disclosure is not limited thereto. For example, in case that the display device 500 is folded at an angle greater than or less than about 180°, e.g., at an angle of greater than or equal to about 90° but less than about 180° or an angle of greater than or equal to about 120° and less than about 180°, the display device 500 may be also referred to as being folded. Even in case that the display device 500 is not completely folded, the display device 500 may be referred to as being folded if the display device 500 is not unfolded but is somewhat bent. For example, even in case that the display device 500 is bent at an angle of equal to or less than about 90°, the display device 500 may be referred to as being folded in order to distinguish it from being unfolded as long as the maximum folding angle is greater than or equal to about 90°. In case that the display device 500 is folded, a radius of curvature may be equal to or less than about 5 mm. For example, in case that the display device 500 is folded, a radius of curvature may be in a range of about 1 mm to about 2 mm. For example, in case that the display device 500 is folded, a radius of curvature may be about 1.5 mm. However, the disclosure is not limited thereto.

According to an embodiment of the disclosure, the display device 500 may include a folding area FDA, a first non-folding area NFA1, and a second non-folding area NFA2. The display device 500 may be folded at the folding area FDA, and the display device 500 may not be folded at the first non-folding area NFA1 and the second non-folding area NFA2.

The first non-folding area NFA1 may be disposed on a side, for example, the upper side of the folding area FDA. The second non-folding area NFA2 may be disposed on another side, for example, the lower side of the folding area FDA. The folding area FDA may be a bendable area with a curvature.

According to an embodiment, the folding area FDA may be located at a position (e.g., a particular position) on the display device 500. In the display device 500, one or more folding areas FDA may be located at particular position(s). In another embodiment, the folding area FDA may not be fixed on an area of the display device 500 and may be freely determined in different areas.

According to an embodiment, the display device 500 may be foldable in the second direction DR2. Accordingly, a length of the display device 500 in the second direction DR2 may be reduced to about half, so that the display device 500 is readily carriable.

However, the folding direction of the display device 500 is not limited to the second direction DR2. For example, the display device 500 may be folded in the first direction DR1, and a length of the display device 500 in the first direction DR1 may be reduced to about half.

Referring to FIGS. 2 and 3, each of the display area DA and the non-display area NDA may overlap the folding area FDA, the first non-folding area NFA1, and the second non-folding area NFA2 in a plan view. However, the disclosure is not limited thereto. For example, each of the display area DA and the non-display area NDA may overlap at least one of the folding area FDA, the first non-folding area NFA1, and the second non-folding area NFA2 in a plan view.

FIG. 4 is a schematic cross-sectional view of a glass article being employed as a cover window of a display device according to an embodiment of the disclosure.

Referring to FIG. 4, the display device 500 may include a display panel 200, a glass article 100 disposed on the display panel 200 and working as a cover window, and an optically transparent coupling layer 300 disposed between the display panel 200 and the glass article 100 to couple the display panel 200 and the glass article 100.

The display panel 200 may be, for example, a self-luminous display panel such as an organic light-emitting display panel (OLED), an inorganic light-emitting display panel (inorganic EL), a quantum-dot light-emitting display panel (QED), a micro LED display panel (micro-LED), a nano LED display panel (nano-LED), a plasma display panel (PDP), a field emission display panel (FED), a cathode ray display panel (CRT), and the like, as well as a light-receiving display panel such as a liquid-crystal display panel (LCD), an electrophoretic display panel (EPD), and the like.

The display panel 200 may include multiple pixels PX and may display images by using light emitted from each of the pixels PX. The display device 500 may further include a touch member (not shown). According to an embodiment of the disclosure, the touch member may be incorporated into the display panel 200. For example, the touch member may be formed directly on a display member of the display panel 200 and the display panel 200 itself may perform a touch function. In another embodiment, the touch member may be fabricated separately from the display panel 200 and attached to an upper surface of the display panel 200 by an optically transparent coupling layer 300.

The glass article 100 protecting the display panel 200 may be disposed above (or on) the display panel 200. The glass article 100 may be larger than the display panel 200 so that side surfaces of the glass article 100 may protrude outwardly from side surfaces of the display panel 200. However, the disclosure is not limited thereto. The display device 500 may further include a printed layer (not shown) disposed on at least one surface of the glass article 100 at an edge of the glass article 100. The printed layer of the display device 500 may hide a bezel of the display device 500 from an outside and may give a decoration in implementations.

The optically transparent coupling layer 300 may be disposed between the display panel 200 and the glass article 100. The optically transparent coupling layer 300 may serve to fix the glass article 100 on the display panel 200. The optically transparent coupling layer 300 may include an optically clear adhesive (OCA), an optically clear resin (OCR), or the like. Hereinafter, the above-described strengthened glass article 100 will be described in more detail.

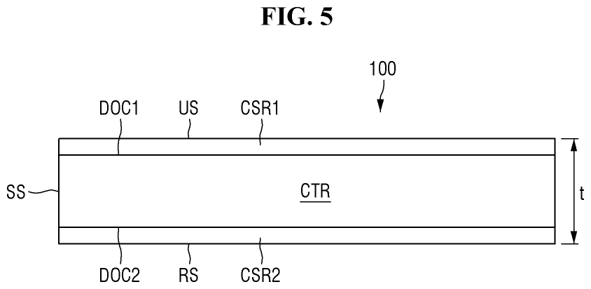

FIG. 5 is a schematic cross-sectional view of a glass article having a shape of a flat plate according to an embodiment of the disclosure.

Referring to FIG. 5, the glass article 100 may include a first surface US, a second surface RS, and side surfaces SS. In the glass article 100 having a shape of a flat plate, the first surface US and the second surface RS may be main surfaces having a large area, and side surfaces SS may be outer surfaces connecting the first surface US with the second surface RS.

The first surface US and the second surface RS may be opposed to each other in the thickness direction of the glass article 100. In case that the glass article 100 serves to transmit light like a cover window of a display device (see, e.g., 500 of FIG. 4), the light may be incident on one of the first surface US and the second surface RS to exit through another one of the first surface US and the second surface RS.

A thickness t of the glass article 100 may be defined as a distance between the first surface US and the second surface RS. The thickness t of the glass article 100 may be, but is not limited to, equal to or less than about 100 μm. For example, the thickness t of the glass article 100 may be in a range of about 20 μm to about 100 μm. According to an embodiment of the disclosure, the thickness t of the glass article 100 may be equal to or less than about 80 μm. In another embodiment, the thickness t of the glass article 100 may be equal to or less than about 75 μm. In another embodiment, the thickness t of the glass article 100 may be equal to or less than about 70 μm. In another embodiment, the thickness t of the glass article 100 may be equal to or less than about 60 μm. In another embodiment, the thickness t of the glass article 100 may be equal to or less than about 65 μm. In another embodiment, the thickness t of the glass article 100 may be equal to or less than about 50 μm. In another embodiment, the thickness t of the glass article 100 may be equal to or less than about 30 μm. In embodiments, the thickness t of the glass article 100 may be in a range of about 20 μm to about 50 μm. For example, the thickness of the glass article 100 may be about 30 μm. The glass article 100 may have a uniform thickness t or may have different thicknesses on different regions in the thickness direction of the glass article 100.

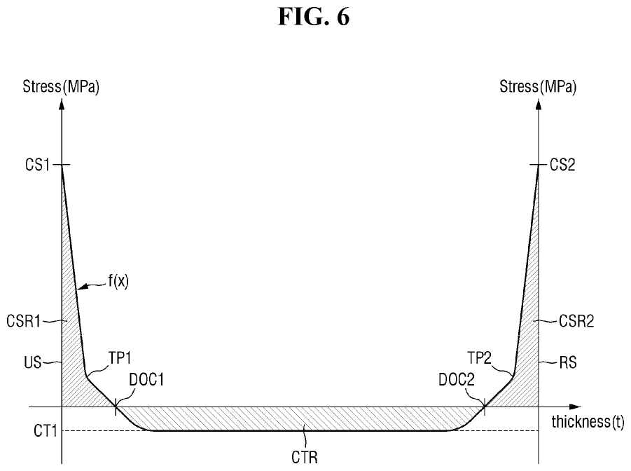

The glass article 100 may be strengthened to have a stress profile (e.g., a predetermined or selectable stress profile) in the glass article 100. The strengthened glass article 100 may better prevent cracks generation, propagation of cracks, breakage, or the like due to external impact, compared to the glass article 100 not strengthened. The glass article 100 strengthened through a strengthening process may have different stresses depending on different regions in the glass article 100. For example, compressive regions CSR1 and CSR2 where compressive stress formed may be disposed in the vicinity of surfaces of the glass article 100, i.e., near the first surface US and the second surface RS, and a tensile region CTR where tensile stress formed may be disposed inside the glass article 100. Stress values of the boundaries DOC1 and DOC2 between the compression regions CSR1 and CSR2 and the tension region CTR may be about 0 MPa. A value of the compressive stress (sec. TP1 and TP2 of each of the compressive regions CSR1 and CSR2 in FIG. 6) in each of the compressive regions CSR1 and CSR2 may vary depending on a position (i.e., depth from a surface of the compressive regions CSR1 and CSR2). The tensile region CTR may also have different stress values depending on a depth from the surfaces US and RS in the thickness direction of the glass article 100.

The position of the compressive regions CSR1 and CSR2 in the glass article 100, the stress profile in the compressive regions CSR1 and CSR2, the compressive energy of the compressive regions CSR1 and CSR2, the tensile energy of the tensile region CTR or the like may affect greatly on the mechanical properties of the glass article 100, such as surface strength or the like.

FIG. 6 is a schematic graph showing the stress profile of a glass article according to an embodiment of the disclosure. In the graph of FIG. 6, x-axis represents the thickness direction of the glass article 100. In FIG. 6, the compressive stress may have positive values, and the tensile stress may have negative values. Magnitudes of the compressive/tensile stresses may be the absolute values regardless of signs of the compressive/tensile stresses.

Referring to FIG. 6, the glass article 100 may include a first compressive region CSR1 that is extended (or expanded) from the first surface US to a first compression depth DOC1, and a second compressive region CSR2 that is extended (or expanded) from the second surface RS to a second compression depth DOC2. A tensile region CTR may be disposed between the first compression depth DOL1 and the second compression depth DOL2. The stress profile on the first surface US and the stress profile on the second surface RS of the glass article 100 may be symmetrical with respect to a center of the glass article 100 in the thickness (t in FIG. 5) direction. Although not shown in FIG. 6, compressive regions and a tensile region may be formed between opposed side surfaces (see, e.g., SS of FIG. 5) of the glass article 100 in a similar manner.

The first compressive region CSR1 and the second compressive region CSR2 may be resistant to an external impact to prevent cracks in the glass article 100 or damage to the glass article 100. The larger the maximum compression stresses CS1 and CS2 of the first compressive region CSR1 and the second compressive region CSR2 are, the higher the strength of the glass article 100 may be. Since an external impact is usually transmitted through the surfaces of the glass article 100, it may be advantageous to have the maximum compressive stresses CS1 and CS2 at the surfaces of the glass article 100 in terms of durability. In view of the above, the compressive stresses of the first compressive region CSR1 and the second compressive region CSR2 may be the largest at the surfaces and generally decrease toward the center.

The first compression depth DOC1 and the second compression depth DOC2 may suppress cracks or grooves formed on the first surface US and the second surface RS from propagating to the tensile region CTR inside the glass article 100. The larger the first compression depth DOC1 and the second compression depth DOC2 are, the better the propagation of cracks and the like may be prevented. The positions of the first compression depth DOC1 and the second compression depth DOC2 may be boundaries between the tension region CTR and each of the compressive regions CSR1 and CSR2, where the stress value is about 0 MPa.

Throughout the glass article 100, the tensile stress of the tensile region CTR may be balanced with the compressive stresses of the compressive regions CSR1 and CSR2. For example, in the glass article 100, the sum of the compressive stresses (i.e., the compressive energies) may be equal to the sum of tensile stresses (i.e., the tensile energies). The stress energies accumulated in an area having a constant width in the thickness t direction in the glass article 100 may be calculated by integrating the stress profile. In case that the stress profile in the glass article 100 having the thickness of t is represented by function f(x), the following Equation 1 may be satisfied.

$${\int }_{0}^{t} f ( x ) d x = 0 \qquad [ Equation 1 ]$$

The larger the tensile stress inside the glass article 100 is, the more likely the broken pieces may be strongly scattered in case that the glass article 100 is broken, and the more likely the glass article 100 may be crushed from the inside. For example, the maximum tensile stress that meets the frangibility requirements of the glass article 100 may satisfy the following Equation 2.

$$C {T}_{1} \leq - 38.7 \times In ( t ) + 48.2 \qquad [ Equation 2 ]$$

In an embodiment, the maximum tensile stress CT1 may be equal to or less than about 100 MPa. For example, the maximum tensile stress CT1 may be equal to or less than about 85 MPa. In order to improve mechanical properties such as strength or the like, it may be desirable that the maximum tensile stress CT1 is greater than or equal to about 75 MPa. According to an embodiment of the disclosure, the maximum tensile stress CT1 may be, but is not limited to, in a range of about 75 MPa to about 85 MPa.

The maximum tensile stress CT1 of the glass article 100 may be generally located at the center portion of the glass article 100 in the thickness t direction. For example, the maximum tensile stress CT1 of the glass article 100 may be located at a depth in a range of about 0.4 t to about 0.6 t. For example, the maximum tensile stress CT1 of the glass article 100 may be located at a depth in a range of about 0.45 t to about 0.55 t. For example, the maximum tensile stress CT1 of the glass article 100 may be located at a depth at a depth of about 0.5 t.

Although it is advantageous that the compressive stresses and the compression depths DOL1 and DOL2 have large values in order to increase the strength of the glass article 100, the tensile stress may also be increased as the tensile energy is increased with the compressive energy. In order to meet the frangibility requirements while having a high strength, it may be desired to adjust the stress profile so that the maximum compressive stresses CS1 and CS2 and the compression depths DOL1 and DOL2 have large values while the compressive energy is reduced. To this end, the glass article 100 may be produced by a glass composition including certain components in contents (e.g., predetermined or selectable contents). Depending on the composition ratio of the components included in the glass composition, the glass article 100 may have excellent strength, as well as flexibility and properties so that it can be applied to a foldable display device.

According to an embodiment of the disclosure, the glass composition forming the glass article 100 may include SiO₂ content in a range of about 48 mol % to about 57 mol %, Al₂O₃ content in a range of about 10 mol % to about 20 mol %, Na₂O content in a range of about 8 mol % to about 18 mol %, K₂O content greater than about 0 mol % and equal to or less than about 10 mol %, B₂O₃ content in a range of about 10 mol % to about 17 mol %, and CaO or MgO content greater than about 0 mol % and equal to or less than about 7 mol % based on the total weight of the glass composition.

The components of the glass composition will be described in more detail as follows.

The glass may consist of SiO₂, which can increase chemical durability and can suppress cracks in case that scratches (indentations) are formed on a surface of the glass. SiO₂ may be a network former oxide that forms a network of glass. The glass article 100 produced with SiO₂ may have a reduced coefficient of thermal expansion and improved mechanical strength. In order to sufficiently achieve the above effects, SiO₂ content may be greater than or equal to about 48 mol %. In order to have sufficient fusibility, SiO₂ content may be equal to or less than about 57 mol % in the glass composition.

Al₂O₃ may provide the glass with better characteristics in case that the glass is broken.

For example, in case that a glass is broken, Al₂O₃ may reduce the number of broken pieces. Al₂O₃ may be an intermediate oxide forming a bond with SiO₂ forming a network structure. Al₂O₃ may act as an effective component that improves ion exchange during chemical strengthening and increases surface compressive stress after the strengthening. In case that the content of Al₂O₃ is greater than or equal to about 10 mol %, the above effects may be effectively achieved. On the other hand, in order to maintain an acid resistance and fusibility of the glass, it may be desired that the content of Al₂O₃ is equal to or less than about 20 mol %.

Na₂O may serve to create surface compressive stress by ion exchange and to improve the fusibility of the glass. Na₂O may form non-bridging oxygen in a network structure of SiO₂ by forming an ionic bond with the oxygen of SiO₂ forming the network structure. By increasing the non-bridging oxygen, it may be possible to improve the flexibility of the network structure, and the glass article 100 may have physical properties applicable to a foldable display device. In order to effectively achieve the above effects, it may be desired that the content of Na₂O is greater than or equal to about 8 mol %. On the other hand, in terms of acid resistance of the glass article 100, it may be desired that the content of Na₂O is equal to or less than about 18 mol %.

K₂O may substitute Na with K, thereby increasing the compressive stress of the glass. Accordingly, K₂O may improve folding reliability and bending reliability of the glass article 100 to thereby contribute to implementing the flexible glass article 100. The effect may be achieved in case that the K₂O content is greater than about 0 mol %. On the other hand, in terms of fusibility of the glass article 100, it may be desired that the K₂O content is equal to or less than about 10 mol %.

B₂O₃ may improve a chemical durability and flexibility of the glass and improve the fusibility. B₂O₃ may also be a network former oxide that forms the network structure together with SiO₂. B₂O₃ may have a coordination number of 3 and bonding force of B₂O₃ may be lower than bonding force of Al₂O₃, which can reduce a modulus of elasticity. Accordingly, in case that the content of B₂O₃ is greater than or equal to about 10 mol %, it may be possible to improve the flexibility of the glass and improve a bending characteristics of the foldable display device. In case that the B₂O₃ content is equal to or less than about 17 mol %, striae may be advantageously suppressed during fusing.

MgO may improve the surface strength of the glass and reduce the formation temperature of the glass. MgO may be a network modifier oxide that modifies the network structure of SiO₂ forming the network structure. MgO may reduce the refractive index of the glass and adjust the thermal expansion coefficient and modulus of elasticity of the glass. The effect may be achieved in case that the MgO content is greater than about 0 mol %. On the other hand, in terms of fusibility of the glass article 100, it may be desired that the MgO content is equal to or less than about 7 mol %.

CaO may improve the surface strength of the glass. CaO may be a network modifier oxide that modifies the SiO₂ network structure forming the network structure. CaO may increase a glass transition temperature of the glass and improve chemical durability. The effect may be achieved in case that the CaO content is greater than about 0 mol %. On the other hand, in terms of fusibility of the glass article 100, it may be desired that the CaO content is equal to or less than about 7 mol %.

According to an embodiment, the glass composition may satisfy the following Condition 1.

$$about 0.7 \leq {Al}_{2} {O}_{3} / ( {Na}_{2} O + {K}_{2} O ) ( R ratio ) \leq about 1.3 \qquad [ Condition 1 ]$$

Al₂O₃, Na₂O, and K₂O may be the contents in mol % in the glass composition.

As described above, the glass article 100 produced by the glass composition according to an embodiment may have characteristics and physical properties applicable to a foldable display device. For example, the glass article 100 may have flexibility to allow folding and unfolding, and strength and chemical properties sufficient to be applied as a cover window of the display device 500. The network structure formed by including SiO₂, B₂O₃, and Al₂O₃ in the glass composition may become a flexible network structure by adding Na₂O and K₂O. By adding Na₂O and K₂O, Na ions or K ions may form ionic bonds with oxygen between bonds forming the network structure, for example, bonds between SiO₂, so that non-bridging oxygen may increase. An increase in non-bridging oxygen within the network structure may mean that the bonds of the network structure are broken or open, and accordingly, the network structure of the glass may have flexibility. The glass composition may include Na₂O content of greater than or equal to about 8 mol % and K₂O content greater than 0 mol % so that the glass article 100 produced may have sufficient flexibility.

As the glass composition includes relatively large contents of Na₂O and K₂O, it may have poor mechanical strength. To compensate for the poor mechanical strength, the glass composition may include Al₂O₃. As a ratio of the Al₂O₃ content to a sum of Na₂O and K₂O is adjusted in a range of about 0.7 to about 1.3 according to Condition 1 above, a mechanical strength of the network structure may be reinforced. According to an embodiment, the glass composition may have the ratio of Al₂O₃ content to the sum of Na₂O and K₂O contents, or R ratio, in a range of about 0.7 to about 1.3.

As the ratio of Al₂O₃ content to the sum of Na₂O and K₂O contents (R ratio) included in the glass composition increases, Al₂O₃ may have a tetrahedron crystal structure formed by SiO₂. In the network structure formed by SiO₂, SiO₂ may have a tetrahedral crystal structure ([SiO₄]). In case that the content of Al₂O₃ is similar to the sum of the contents of Na₂O and K₂O, Al₂O₃ may also have a tetrahedral crystal structure ([AlO₄]). The content of non-bridging oxygen formed by adding Na₂O and K₂O may be reduced, and ion mobility of the glass composition may be increased. An increase in ion mobility may mean that the number of ions moving in a chemical strengthening process in a process of formed the glass article 100 increases and a penetration depth of the ions increases, and the mechanical strength of the surface of the glass article 100 may be improved.

In case that the ratio of the Al₂O₃ content to the sum of the Na₂O and K₂O contents (R ratio) in the glass composition has a value of greater than or equal to about 0.7, the Na₂O and K₂O contents may increase and the increased Na₂O and K₂O may break the network structure of SiO₂. As a result, a distance between atoms in the network structure may be increased. Accordingly, a large extra space may be formed in the network structure of SiO₂, so that shock may be absorbed more efficiently.

According to an embodiment of the disclosure, the ratio of the Al₂O₃ content to the sum of the Na₂O and K₂O contents (R ratio) in the glass composition may be in a range of about 0.7 to about 1.3, thereby providing flexibility of the glass article 100 and sufficient resistance to external impact and improving shock absorption.

In an embodiment, the glass composition may include about 52 mol % of SiO₂, about 15 mol % of Al₂O₃, about 13 mol % of Na₂O, about 3 mol % of K₂O, about 5 mol % of MgO, and about 12 mol % of B₂O₃, and the R ratio in Condition 1 above may be about 0.93. In another embodiment, the glass composition may include about 52 mol % of SiO₂, about 15 mol % of Al₂O₃, about 13 mol % of Na₂O, about 3 mol % of K₂O, about 5 mol % of CaO, and about 12 mol % of B₂O₃, and the R ratio in Condition 1 above may be about 0.93.

The glass composition may include B₂O₃ to provide flexibility so that the glass article 100 can be folded and unfolded. B₂O₃ may form the glass with the coordination number of 3 to lower the bonding strength, such as the viscosity. Accordingly, folding and unfolding of the glass article 100 may be improved by reducing the glass transition temperature and modulus of elasticity of the glass. As the modulus of elasticity of the glass is reduced, the stress applied to the lower portion of the glass article during folding and unfolding may be reduced, thereby improving the bending characteristics of the glass article. It may be possible to improve impact resistance by lowering the modulus of elasticity that is inversely proportional to a probability of molecular vibration upon impact and increasing a free volume fraction that is proportional to impact energy.

The glass composition may include CaO or MgO content that is greater than about 0 mol % and equal to or less than about 7 mol %. As described above, CaO or MgO may improve the strength of the glass, but may increase the viscosity of the glass composition and the modulus of elasticity of the glass as well. According to an embodiment where the modulus of elasticity of the glass is reduced, a small content of CaO or MgO may be included in order to improve the strength of the glass.

The glass composition may further include components such as Y₂O₃, La₂O₃, Nb₂O₅, Ta₂O₅, and Gd₂O₃ as desired, in addition to the components listed above. A small amount of Sb₂O₃, CeO₂, and/or As₂O₃ may be further included as a fining agent.

The glass composition having the above compositions may be formed into a plate glass shape by various methods available in the art. Once the glass composition is formed into a plate glass shape, it may be further processed to be produced into the glass article 100 applicable to the display device 500. However, the disclosure is not limited thereto. Instead of the plate glass shape, the glass composition may be directly formed into the glass article 100 applicable to a display device without an additional process.

Hereinafter, a process in which a glass composition is formed into a plate glass shape and the glass is processed into the glass article 100 will be described.

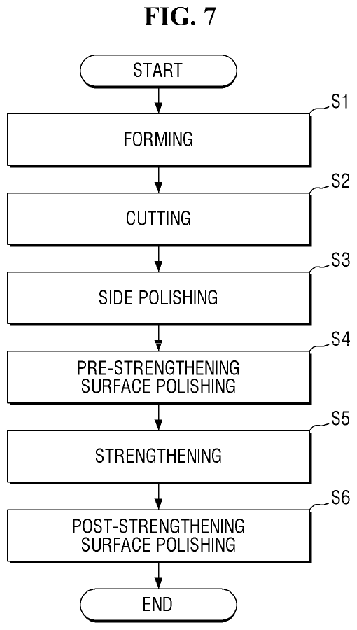

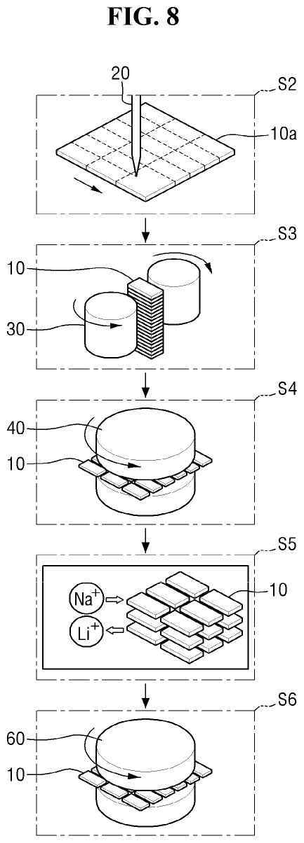

FIG. 7 is a schematic flowchart for illustrating processing steps for producing the glass article according to an embodiment of the disclosure. FIG. 8 is a schematic flowchart illustrating processing steps from a cutting to a post-strengthening surface polishing of FIG. 7.

Referring to FIGS. 7 and 8, a method of producing the glass article 100 may include forming (step S1), cutting (step S2), side polishing (step S3), pre-strengthening surface polishing (step S4), strengthening (step S5), and post-strengthening surface polishing (step S6).

The forming S1 may include preparing a glass composition, and forming the glass composition. The glass composition may have the compositions and components as described above. The detailed description will be omitted. The glass composition may be formed into a flat glass shape by a float process, a fusion draw process, a slot draw process, or the like.

Glass formed into the flat plate shape may be cut in the cutting S2. The glass formed into the flat plate shape and one applied to the glass article 100 may have different sizes. For example, the glass forming may be carried out on a substrate having a large area as a mother substrate 10a including multiple glass articles. By cutting the substrate having the large area into multiple cells 10, multiple glass articles may be produced. For example, in case that the final glass articles 100 have a size of about 6 inches, a glass may be formed to have a size of several to hundreds of times greater than the final glass articles, for example 120 inches, and may be cut to obtain about 20 glasses formed into a flat plate shape at once. Therefore, the process efficiency may be improved over forming individual glass articles separately. In case that a glass having a size equal to the size of a glass article is formed, a desired shape may be formed by a cutting process to form a final glass article in various shapes.

The glass 10a may be cut using a cutting knife 20, a cutting wheel, a laser, or the like.

The cutting of the glass S2 may be carried out prior to the strengthening of the glass S5. The glass 10a of the mother substrate may be strengthened and may be cut into the size of the final glass articles 100. However, cut surfaces (e.g., the side surfaces of the glass) may not be strengthened. Therefore, it may be desired that the cutting S2 is followed by the strengthening S5.

Polishing before strengthening may be carried out between the cutting of the glass S2 and the strengthening S5. The polishing may include the side polishing S3 and the pre-strengthening surface polishing S4. Although FIG. 7 shows that the side polishing S3 is carried out followed by the pre-strengthening surface polishing S4, an order may be changed.

The side polishing S3 may be a step of polishing the side surfaces of the cut glasses 10. In the side polishing S3, the side surfaces of the glasses 10 may be polished to have a smooth surface. The side surfaces of the glasses 10 may have a uniform surface after the side polishing S3. For example, the cut glasses 10 may include one or more cut surfaces. Some of the cut glasses 10 may have two cut surfaces among the four side surfaces. Another ones of the cut glasses 10 may have three cut surfaces among the four side surfaces. Another ones of the cut glasses 10 may have four cut surfaces. There may be a difference in surface roughness between the cut side surfaces and other side surfaces. There may be a difference in surface roughness between the cut surfaces. Therefore, by polishing each side surface in the side polishing S3, side surfaces may have a uniform surface roughness. Furthermore, in case that there is a small crack on a side surface, it may be removed by the side polishing S3.

The side polishing S3 may be carried out simultaneously on multiple cut glasses 10. A stack of the cut glasses 10 may be simultaneously polished.

The side polishing S3 may be carried out by mechanical polishing, chemical mechanical polishing, the like, or a combination thereof using a polishing device 30. According to an embodiment, two opposing sides of the cut glasses 10 may be polished simultaneously, and another two opposing sides may be simultaneously polished, but the disclosure is not limited thereto.

The pre-strengthening surface polishing S4 may be carried out so that the glasses 10 have a uniform surface. The pre-strengthening surface polishing S4 may be carried out on each of the cut glasses 10 one after another. In case that a chemical mechanical polishing device 40 is much larger than the glasses 10, the glasses 10 may be arranged, and the glasses 10 may be simultaneously polished.

The pre-strengthening surface polishing S4 may be carried out by a chemical mechanical polishing. A first surface and a second surface of each of the cut glasses 10 may be polished using the chemical mechanical polishing device 40 and a polishing slurry. The first surface and the second surface may be polished simultaneously, or one of the surfaces may be polished, and another one of the surfaces may be polished.

After the pre-strengthening surface polishing S4, the strengthening S5 may be carried out. The strengthening S5 may be carried out by a chemical strengthening and/or a thermal tempering. For a glass 10 having a thickness of equal to or less than about 2 mm, a chemical strengthening may be appropriate for precisely controlling the stress profile. For a glass 10 having a thickness of equal to or less than about 0.75 mm, a chemical strengthening may be appropriate for precisely controlling the stress profile.

Optionally, the post-strengthening surface polishing S6 may be further carried out after the strengthening S5. The post-strengthening surface polishing S6 may include removing fine cracks on the surfaces of the strengthened glasses 10, and controlling compressive stress of the first and second surfaces of the strengthened glasses 10. For example, a float method, which is one of the techniques for producing a glass plate, may be carried out by flowing glass compositions into a tin bath. The surface of the glass plate contacting the bath and the surface of the glass plate not contacting the bath may have different compositions. As a result, after the process of the strengthening S5, there may be deviations in the compressive stress between the surface contacting the tin (Sn) and the surface not contacting the tin (Sn). By removing the surface of the glasses to an appropriate thickness by polishing, it may be possible to reduce the deviations in the compressive stresses between the surfaces.

The post-strengthening surface polishing S6 may be carried out by a chemical mechanical polishing. The first and second surfaces of the cut glasses 10 may be polished using a chemical mechanical polishing device 60 and the polishing slurry. For example, a polishing thickness may be adjusted in a range of about 100 nm to about 1,000 nm, but the disclosure is not limited thereto. The first and second surfaces may be polished to the same depth or different depths.

Although not illustrated in the drawings, a shaping process may be further carried out in case that the process is needed after the post-strengthening surface polishing S6. For example, to produce the three-dimensional glass articles 101 to 103 shown in FIG. 1, a three-dimensional shaping process may be carried out after the post-strengthening surface polishing S6 is completed.

The glass articles 100 produced by the above-described processes may include a component ratio similar to a component ratio of the glass composition. The glass article 100 may include SiO₂ content in a range of about 48 mol % to about 57 mol %, Al₂O₃ content in a range of about 10 mol % to about 20 mol %, Na₂O content in a range of about 8 mol % to about 18 mol %, K₂O content greater than about 0 mol % and equal to or less than about 10 mol %, B₂O₃ content in a range of about 10 mol % to about 17 mol %, and CaO or MgO content greater than about 0 mol % and equal to or less than about 7 mol %. The glass composition for producing the glass article 100 may satisfy the following Condition 1.

$$about 0.7 \leq {Al}_{2} {O}_{3} / ( {Na}_{2} O + {K}_{2} O ) ( R ratio ) \leq about 1.3 \qquad [ Condition 1 ]$$

Al₂O₃, Na₂O, and K₂O may be the contents in mol %.

According to an embodiment of the disclosure, the glass articles 100 produced from the above-described glass composition may have a thickness of equal to less than about 100 μm and may satisfy the following physical properties. For example, the glass articles 100 produced from the above-described glass composition may have a thickness in a range of about 20 μm to about 100 μm and may satisfy the following physical properties.
i) glass transition temperature (Tg): in a range of about 510° C. to about 610° C.
ii) density: in a range of about 2.45 g/cm³ to about 2.60 g/cm³
iii) modulus of elasticity: in a range of about 60 GPa to about 70 GPa
iv) hardness: in a range of about 4.8 GPa to about 5.5 GPa
v) fracture toughness: in a range of about 0.75 MPa*m^{0.5} to about 0.83 MPa*m^{0.5}
vi) brittleness: in a range of about 6.0 μm^{-0.5} to about 7.0 μm^{-0.5}
vii) coefficient of thermal expansion (10⁻⁷ K⁻¹): in a range of about 80*10⁻⁷ K⁻¹ to about 90*10⁻⁷ K⁻¹
viii) Poisson ratio: in a range of about 0.23 to about 0.25
ix) crack initiation load: in a range of about 1,500 gf to about 2,500 gf
x) free volume fraction: in a range of about 15,000 to about 20,000

Hereinafter, embodiments will be described in more detail with reference to Example and Experimental Examples.

### Example 1: Production of Glass Articles

According to Table 1 below, multiple glass substrates having various compositions were prepared, sorted into SAMPLE #1, SAMPLE #2, and SAMPLE #3, and processes for producing glass articles were carried out for each SAMPLE according to the above-described method. Glass article for each sample was produced to have a thickness of about 50 μm.

The composition of the glass article for each sample is shown in Table 1 below. The density, glass transition temperature, hardness, fracture toughness, brittleness, modulus of elasticity, coefficient of thermal expansion, Poisson ratio, crack initiation load, and free volume fraction of the glass article for each sample were measured and shown in Table 2 below.

The glass transition temperature (Tg) was obtained by preparing about 5 g for each composition, increasing the temperature at the rate of about 10 K/min to the glass transition temperature range, and measuring the transition temperature using a differential thermal analysis (DTA) apparatus. The thermal expansion coefficient of the glass was obtained by preparing a specimen of about 10×10×13 mm³ for each composition, increasing the temperature at the rate of about 10 K/min to the glass transition temperature range, and measuring it using a thermo mechanical analyzer (TMA).

The elastic modulus and Poisson ratio were obtained by preparing a specimen of about 10×20×3 mm³ for each composition and measuring the stress and strain of the specimen using an elastic modulus tester.

The hardness and fracture toughness were obtained by applying the load of about 4.9 N for about 30 seconds with a Vickers hardness tester using a diamond tip having a size of about 19 μm and calculating using Equations 3 and 4 below.

$${H}_{V} = 1.854 * \frac{F}{{a}^{2}} \qquad [ Equation 3 ]$$

H_{V} may be the Vickers hardness, F may be the load, and a may be the indentation length.

$$\frac{{K}_{IC} * ∅}{{H}_{V} * {a}^{\frac{1}{2}}} = 0.15 * K * {( \frac{c}{a} )}^{- \frac{3}{2}} \qquad [ Equation 4 ]$$

KIC may be the fracture toughness, ϕ may be the constraint index (ϕ≈about 3), H_{V} may be the Vickers hardness, K may be a constant (=about 3.2), c may be the crack length, and a may be the indentation length.

The brittleness was calculated by Equation 5 below by applying the load of about 4.9 N for about 30 seconds using the Vickers hardness tester.

$$B = γ {P}^{- 1 / 4} {\frac{C}{a}}^{3 / 2} \qquad [ Equation 5 ]$$

B may be a brittleness, y may be a constant (about 2.39 N^{1/4}/μm^{1/2}), P may be the indentation load, a may be the indentation length, and C may be the crack length.

The crack initiation load was measured using a Vickers hardness tester.

The free volume fraction was calculated by Equation 6 below.

$$E I R = \frac{{( {F}_{F} )}^{2}}{2 E} * {R}_{f} \qquad [ Equation 6 ]$$

EIR may be the edge impact resistance. E may be the modulus of elasticity. F_{f} may be the fracture force, and R_{f} may be the fractional free volume.

TABLE 1

| | SAMPLE | SAMPLE | SAMPLE |
|---|---|---|---|
| Sample group | #1 | #2 | #3 |

| | | | | |
|---|---|---|---|---|
| Composition | SiO₂ | 52.0 | 52.0 | 70.0 |
| | Al₂O₃ | 15.0 | 15.0 | 7.7 |
| | B₂O₃ | 12.0 | 12.0 | — |
| | MgO | 5.0 | — | 7.5 |
| | Na₂O | 13.0 | 13.0 | 12.7 |
| | K₂O | 3.0 | 3.0 | 1.7 |
| | CaO | — | 5.0 | — |

| | | | |
|---|---|---|---|
| Composition Ratio | 15:16 | 15:16 | 7.7:14.4 |
| (mol %) Al₂O₃:R₂O | | | |
| Composition Ratio | 0.93 | 0.93 | 0.53 |
| (mol %) Al₂O₃/R₂O | | | |

TABLE 2

| | | | | |
|---|---|---|---|---|
| Physical | Density (g/cm³) | 2.503 | 2.555 | 2.46 |
| properties | Glass transition | 560 | 581 | 602 |
| | temperature Tg (° C.) | | | |
| | Hardness (GPa) | 5.06 | 5.30 | 6.05 |
| | Fracture toughness | 0.79 | 0.78 | 0.70 |
| | (MPa*m^{0.5}) | | | |
| | Brittleness (μm^{-0.5}) | 6.4 | 6.8 | 8.64 |
| | Modulus of | 63 | 67 | 74 |
| | elasticity (GPa) | | | |
| | Coefficient of thermal | 85.6 | 85.9 | 88.0 |
| | expansion (10⁻⁷ K⁻¹) | | | |
| | Poison's ratio | 0.237 | 0.242 | 0.220 |
| | Crack initiation | 2000 | 2000 | 500 |
| | load (gf) | | | |
| | Free volume | 19841 | 15356 | 12419 |
| | fraction | | | |

Referring to Tables 1 and 2, the glass articles of SAMPLE #1 and SAMPLE #2 were made of the glass composition according to an embodiment, while the glass article of SAMPLE #3 is Comparative Example.

It may be seen that SAMPLE #1 and SAMPLE #2 have lower glass transition temperatures than SAMPLE #3. Accordingly, it may be possible to lower the probability of molecular vibration upon impact with low glass transition temperatures, which may mean that the impact resistance is excellent.

It may be seen that SAMPLE #1 and SAMPLE #2 have lower elastic moduli than SAMPLE #3. Accordingly, it may be possible to improve the surface breakage energy with low elastic moduli, which may mean that the bending properties of folding and unfolding are excellent.

It may be seen that SAMPLE #1 and SAMPLE #2 have higher crack initiation loads than SAMPLE #3. Accordingly, it may mean that excellent impact resistance due to higher crack initiation loads.

It may be seen that SAMPLE #1 and SAMPLE #2 have higher fractional free volumes than SAMPLE #3. Accordingly, it may mean that excellent impact resistance due to higher fractional free volumes.

### Experimental Example 1: Impact Resistance Evaluation—Pen Drop (Pen Diameter about 0.7π) Evaluation

Pen-drop test (PDT) was carried out on SAMPLE #1, SAMPLE #2, and SAMPLE #3 of Table 1 above. The pen-drop test was carried out by dropping a pen with a diameter of about 0.7π onto the surface of the fixed sample articles to check the height at which a crack occurs on the surface of the articles. The drop height of the pen was increased by about 0.1 cm, and was in a range of about 0.5 cm to about 10 cm. The pen drop was repeated until a crack occurs on the surface. The height just before the crack occurs (e.g., the maximum height at which the surface is not broken) was determined as the limit drop height. The results are shown in Table 3 below. The pen-drop test was carried out on each of the samples after the strengthening during the glass producing process.

TABLE 3

| | Pen Drop Break |
|---|---|
| | Height (cm) |
| SAMPLE #1 | 2.50 |
| SAMPLE #2 | 2.63 |
| SAMPLE #3 | 2.50 |

It may be seen from Table 3 that SAMPLES #1, #2, and #3 showed the pen-drop breakage heights of about 2.50 cm, about 2.63 cm, and about 2.50 cm, respectively, which are similar.

It may be seen from the above that SAMPLE #1 and SAMPLE #2 exhibit excellent bending characteristics and pen-drop test results equivalent to the bending characteristics and pen-drop test result of Comparative Example. The glass article 100 according to an embodiment may have an average limit drop height of greater than or equal to about 2.5 cm from the pen-drop test with the pen having the diameter of about 0.7π.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A glass article prepared from a glass composition comprising:
SiO₂ in a range of about 48 mol % to about 57 mol %;
Al₂O₃ in a range of about 10 mol % to about 20 mol %;
Na₂O in a range of about 8 mol % to about 18 mol %;
K₂O greater than 0 mol % and equal to or less than about 10 mol %;
B₂O₃ in a range of about 10 mol % to about 17 mol %; and
CaO or MgO greater than 0 mol % and equal to or less than about 7 mol % based on a total weight, wherein
the glass composition satisfies Condition 1 below:
$$about 0.7 \leq {Al}_{2} {O}_{3} / ( {Na}_{2} O + {K}_{2} O ) \leq about 1.3 , \qquad [ Condition 1 ]$$
Al₂O₃, Na₂O, and K₂O are contents in mol % in the glass composition, and
a thickness of the glass article is equal to or less than about 100 μm.

2. The glass article of claim 1, wherein the thickness of the glass article is in a range of about 20 μm to about 100 μm.

3. The glass article of claim 1, wherein a glass transition temperature of the glass article is in a range of about 510° C. to about 610° C.

4. The glass article of claim 1, wherein a density of the glass article is in a range of about 2.45 g/cm³ to about 2.60 g/cm³.

5. The glass article of claim 1, wherein a modulus of elasticity of the glass article is in a range of about 60 GPa to about 70 GPa.

6. The glass article of claim 1, wherein a hardness of the glass article is in a range of about 4.8 GPa to about 5.5 GPa.

7. The glass article of claim 1, wherein a fracture toughness of the glass article is in a range of about 0.75 MPa*m^{0.5} to about 0.83 MPa*m^{0.5}.

8. The glass article of claim 1, wherein a brittleness of the glass article is in a range of about 6.0 μm^{-0.5} to about 7.0 μm^{-0.5}.

9. The glass article of claim 1, wherein a coefficient of thermal expansion of the glass article is in a range of about 80*10⁻⁷ K⁻¹ to about 90*10⁻⁷ K⁻¹.

10. The glass article of claim 1, wherein a Poisson ratio of the glass article is in a range of about 0.23 to about 0.25.

11. The glass article of claim 1, wherein a crack initiation load of the glass article is in a range of about 1,500 gf to about 2,500 gf.

12. The glass article of claim 1, wherein a fractional free volume of the glass article is in a range of about 15,000 to about 20,000.

13. The glass article of claim 1, wherein an average of a pen drop breakage height of the glass article is greater than or equal to about 2.5 cm.

14. A glass composition comprising:
SiO₂ in a range of about 48 mol % to about 57 mol %;
Al₂O₃ in a range of about 10 mol % to about 20 mol %;
Na₂O in a range of about 8 mol % to about 18 mol %;
K₂O greater than 0 mol % and equal to or less than about 10 mol %;
B₂O₃ in a range of about 10 mol % to about 17 mol %; and
CaO or MgO greater than 0 mol % and equal to or less than about 7 mol % based on a total weight, wherein
the glass composition satisfies Condition 1 below:
$$about 0.7 \leq {Al}_{2} {O}_{3} / ( {Na}_{2} O + {K}_{2} O ) \leq about 1.3 , \qquad [ Condition 1 ]$$
and
Al₂O₃, Na₂O, and K₂O are contents in mol % in the glass composition.

15. A display device comprising:
a display panel comprising a plurality of pixels;
a cover window disposed above the display panel; and
an optically transparent coupling layer disposed between the display panel and the cover window, wherein
the cover window is prepared from a glass composition comprising:
SiO₂ in a range of about 48 mol % to about 57 mol %;
Al₂O₃ in a range of about 10 mol % to about 20 mol %;
Na₂O in a range of about 8 mol % to about 18 mol %;
K₂O greater than about 0 mol % and equal to or less than about 10 mol %;
B₂O₃ in a range of about 10 mol % to about 17 mol %; and
CaO or MgO greater than about 0 mol % and equal to or less than about 7 mol % based on a total weight,
the glass composition satisfies Condition 1 below,
$$about 0.7 \leq {Al}_{2} {O}_{3} / ( {Na}_{2} O + {K}_{2} O ) \leq about 1.3 , \qquad [ Condition 1 ]$$
Al₂O₃, Na₂O, and K₂O are contents in mol % in the glass composition, and
a thickness of the cover window is equal to or less than about 100 μm.

16. The display device of claim 15, wherein the thickness of the cover window is in a range of about 20 μm to about 100 μm.

17. The display device of claim 15, wherein a glass transition temperature of the cover window is in a range of about 510° C. to about 610° C.

18. The display device of claim 15, wherein a density of the cover window is in a range of about 2.45 g/cm³ to about 2.60 g/cm³.

19. The display device of claim 15, wherein a modulus of elasticity of the cover window is in a range of about 60 GPa to about 70 GPa.

20. The display device of claim 15, wherein a hardness of the cover window is in a range of about 4.8 GPa to about 5.5 GPa.

21. The display device of claim 15, wherein a fracture toughness of the cover window is in a range of about 0.75 MPa*m^{0.5} to about 0.83 MPa*m^{0.5}

22. The display device of claim 15, wherein a brittleness of the cover window is in a range of about 6.0 μm^{-0.5} to about 7.0 μm^{-0.5}.

23. The display device of claim 15, wherein a coefficient of thermal expansion of the cover window is in a range of about 80*10⁻⁷ K⁻¹ to about 90*10⁻⁷ K⁻¹.

24. The display device of claim 15, wherein a Poisson ratio of the cover window is in a range of about 0.23 to about 0.25.

25. The display device of claim 15, wherein a crack initiation load of the cover window is in a range of about 1,500 gf to about 2,500 gf.

26. The display device of claim 15, wherein a fractional free volume of the cover window is in a range of about 15,000 to about 20,000.
